(19) United States
(12) Patent Application Publication
(10) Pub. No.: US 2014/0353470 A1
(43) Pub. Date: Dec. 4, 2014

(54) DETECTION APPARATUS, METHOD OF MANUFACTURING THE SAME, AND RADIATION DETECTION SYSTEM

(71) Applicant: CANON KABUSHIKI KAISHA, Tokyo (JP)

(72) Inventors: Jun Kawanabe, Kumagaya-shi (JP); Minoru Watanabe, Honjo-shi (JP); Keigo Yokoyama, Honjo-shi (JP); Masato Ofuji, Takasaki-shi (JP); Kentaro Fujiyoshi, Tokyo (JP); Hiroshi Wayama, Saitama-shi (JP)

(21) Appl. No.: 14/288,816

(22) Filed: May 28, 2014

(30) Foreign Application Priority Data
Jun. 4, 2013 (JP) 2013-118302

(51) Int. Cl. H01L 27/146

(52) U.S. Cl. CPC H01L 27/1462; H01L 27/14687
USPC 250/208.1; 438/73; 257/448

(57) ABSTRACT

A method of manufacturing a detection apparatus including pixels is provided. The method includes forming an organic insulation layer above a substrate above which a switching element is formed, forming pixel electrodes divided for individual pixels above the organic insulation layer; forming an inorganic material portion above a portion of the organic insulation layer, which is uncovered with the pixel electrodes, forming an inorganic insulation film covering the plurality of pixel electrodes and the inorganic material portion, forming a semiconductor film covering the inorganic insulation film, and dividing the semiconductor film for individual pixels by etching using a stacked structure of the inorganic material portion and the inorganic insulation film as an etching stopper.

### BACKGROUND OF THE INVENTION

1. Field of the Invention

The present invention relates to a detection apparatus, a method of manufacturing the same, and a radiation detection system.

2. Description of the Related Art

Japanese Patent Laid-Open No. 2007-059887 proposes a detection apparatus including a conversion element and a switching element such as a TFT. In this detection apparatus, the conversion element is formed above the switching element, and an interlayer insulation layer is formed between the switching element and the conversion element. The conversion element includes electrodes divided for individual pixels, an insulation layer formed on the electrodes and shared by a plurality of pixels, and semiconductor layers formed on the insulation layer and divided for individual pixels.

### SUMMARY OF THE INVENTION

According to an aspect of the present invention, therefore, there is provided a technique advantageous in thinning the insulation layer included in the conversion element of the detection apparatus.

According to an aspect of the present invention, provided is a method of manufacturing a detection apparatus including a plurality of pixels, comprising: forming an organic insulation layer above a substrate above which a switching element is formed; forming a plurality of pixel electrodes divided for individual pixels above the organic insulation layer; forming an inorganic material portion above a portion of the organic insulation layer, which is uncovered with the plurality of pixel electrodes; forming an inorganic insulation film covering the plurality of pixel electrodes and the inorganic material portion; forming a semiconductor film covering the inorganic insulation film; and dividing the semiconductor film for individual pixels by etching using a stacked structure of the inorganic material portion and the inorganic insulation film as an etching stopper.

According to another aspect of the present invention, provided is a method of manufacturing a detection apparatus including a plurality of pixels, comprising: forming an organic insulation layer above a substrate above which a switching element is formed; forming a plurality of pixel electrodes divided for individual pixels above the organic insulation layer; forming an inorganic insulation film covering the plurality of pixel electrodes and a portion of the organic insulation layer, which is uncovered with the plurality of pixel electrodes; reducing, by etching, a thickness of a second portion of the inorganic insulation film, which exists above the plurality of pixel electrodes, by using a mask covering a first portion of the inorganic insulation film, which exists above the uncovered portion of the organic insulation layer; forming a semiconductor film covering the inorganic insulation film; and dividing the semiconductor film for individual pixels by etching using the first portion of the inorganic insulation film as an etching stopper.

According to yet another aspect of the present invention, provided is a method of manufacturing a detection apparatus including a plurality of pixels, comprising: forming an organic insulation layer above a substrate above which a switching element is formed; forming an inorganic insulation layer above the organic insulation layer; forming a plurality of pixel electrodes divided for individual pixels above the inorganic insulation layer; forming an inorganic insulation film covering the plurality of pixel electrodes and a portion of the inorganic insulation layer, which is uncovered with the plurality of pixel electrodes; forming a semiconductor film covering the inorganic insulation film; and dividing the semiconductor film for individual pixels by etching using a stacked structure of the inorganic insulation layer and the inorganic insulation film as an etching stopper.

According to still another aspect of the present invention, provided is a detection apparatus including a plurality of pixels, comprising: a switching element formed above a substrate; an organic insulation layer formed above the switching element; a plurality of pixel electrodes formed above the organic insulation layer and divided for individual pixels; an inorganic material portion formed above a portion of the organic insulation layer, which is uncovered with the plurality of pixel electrodes; an inorganic insulation layer formed above the plurality of pixel electrodes; and a semiconductor layer formed above the inorganic insulation layer and divided for individual pixels.

According to yet another aspect of the present invention, provided is a detection apparatus including a plurality of pixels, comprising: a switching element formed above a substrate; an organic insulation layer formed above the switching element; a plurality of pixel electrodes formed above the organic insulation layer and divided for individual pixels; an inorganic insulation layer covering a portion of the organic insulation layer, which is uncovered with the plurality of pixel electrodes, and the plurality of pixel electrodes; and a semiconductor layer formed above the inorganic insulation layer and divided for individual pixels, and a portion of the inorganic insulation layer, which has a largest height from the substrate, exists above the uncovered portion of the organic insulation layer.

According to still another aspect of the present invention, provided is a detection apparatus including a plurality of pixels, comprising: a switching element formed above a substrate; an organic insulation layer formed above the switching element; a first inorganic insulation layer formed above the organic insulation layer and having a contact hole which exposes a portion of an electrode of the switching element; a plurality of pixel electrodes formed above the first inorganic insulation layer and divided for individual pixels; a second inorganic insulation layer formed above the plurality of pixel electrodes; and a semiconductor layer formed above the second inorganic insulation layer and divided for individual pixels.

Further features of the present invention will become apparent from the following description of exemplary embodiments (with reference to the attached drawings).

### BRIEF DESCRIPTION OF THE DRAWINGS

FIG. 1 is a view for explaining an equivalent circuit example of a detection apparatus of various embodiments;

FIGS. 2A and 2B are views for explaining a configuration example of a pixel of a detection apparatus of some embodiments;

FIGS. 3A to 3J are views for explaining an example of a method of manufacturing the detection apparatus shown in FIGS. 2A and 2B;

FIG. 4 is a view for explaining the arrangement of the first modification of the detection apparatus shown in FIGS. 2A and 2B;

FIGS. 5A and 5B are views for explaining the arrangement of the second modification of the detection apparatus shown in FIGS. 2A and 2B;

FIGS. 6A and 6B are views for explaining a method of manufacturing the second modification of the detection apparatus shown in FIGS. 2A and 2B;

FIGS. 7A and 7B are views for explaining the arrangement of the third modification of the detection apparatus shown in FIGS. 2A and 2B;

FIGS. 8A to 8D are views for explaining a method of manufacturing the third modification of the detection apparatus shown in FIGS. 2A and 2B;

FIGS. 9A and 9B are views for explaining a configuration example of a pixel of a detection apparatus of some other embodiments;

FIGS. 10A and 10B are views for explaining an example of a method of manufacturing the detection apparatus shown in FIGS. 9A and 9B;

FIGS. 11A and 11B are views for explaining a configuration example of a pixel of a detection apparatus of some other embodiments;

FIGS. 12A and 12B are views for explaining an example of a method of manufacturing the detection apparatus shown in FIGS. 11A and 11B; and

FIG. 13 is a view for explaining a radiation detection system of some other embodiments.

### DESCRIPTION OF THE EMBODIMENTS

In a method of manufacturing the detection apparatus proposed in Japanese Patent Laid-Open No. 2007-059887, portions of a semiconductor film formed on the insulation layer must be removed by etching in order to form the semiconductor layers divided for individual pixels. In this etching, the insulation layer functions as an underlayer. When the film thickness of the insulation layer in a portion in contact with the interlayer insulation layer reduces to a few ten nm by etching, the insulation layer of the conversion element cannot follow the shrinkage of the interlayer insulation layer, which occurs in a heating step of a method of manufacturing the detection apparatus, and the insulation layer of the conversion element may peel off from the interlayer insulation layer. In addition, if an etching gas penetrates through the insulation layer, the interlayer insulation layer below the insulation layer is exposed to etching. If the interlayer insulation layer is exposed to etching when it is made of an organic material, the conversion element is contaminated by the organic material, and a dark current increases.

To prevent film peeling and contamination as described above, the insulation layer need only be formed such that the insulation layer in the portion in contact with the interlayer insulation layer has a sufficient film thickness. In the arrangement of Japanese Patent Laid-Open No. 2007-059887, however, the film thickness of the insulation layer in the portion in contact with the interlayer insulation layer depends on the film thickness of the insulation layer in a portion on the pixel electrode. This makes it difficult to thin the insulation layer in order to increase the sensitivity of the conversion element.

Various embodiments of the present invention will be explained below with reference to the accompanying drawings. The same reference numerals denote the same elements throughout the various embodiments, and a repetitive explanation will be omitted. Also, the embodiments can be changed and combined as needed.

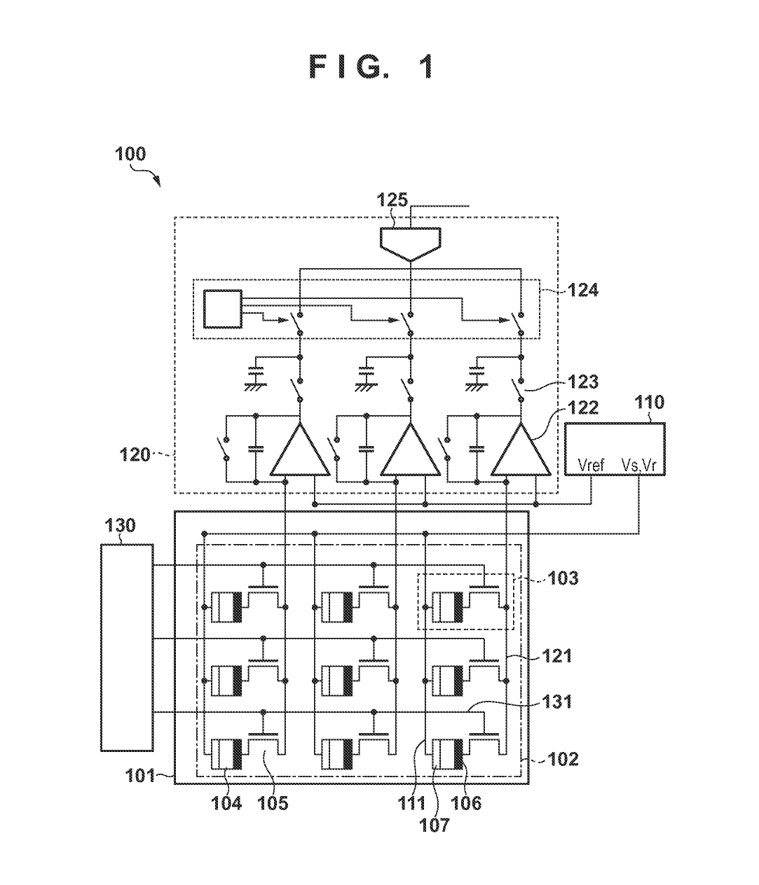

An example of an equivalent circuit of a detection apparatus 100 according to various embodiments of the present invention will be explained with reference to FIG. 1. The detection apparatus 100 is configured to detect emitted radiation. The radiation can be, for example, X-rays, α-rays, β-rays, or γ-rays. The detection apparatus 100 is used in, for example, a medical image diagnostic apparatus, a nondestructive inspection apparatus, or an analyzing apparatus using radiation.

The detection apparatus 100 can include a pixel array 102 formed on a substrate 101. In the pixel array 102, a plurality of pixels 103 are arranged in the form of an array. In the example shown in FIG. 1, the pixel array 102 has 3 rows×3 columns of pixels 103 for the sake of descriptive simplicity. However, the pixel array 102 can include an arbitrary number of rows×an arbitrary number of columns of pixels 103. Each pixel 103 can include a conversion element 104 for converting radiation or light into electric charge, and a TFT (Thin-Film Transistor) 105 that functions as a switching element for outputting an electrical signal corresponding to the electric charge of the conversion element 104. When the conversion element 104 converts light into electric charge, the detection apparatus 100 may have a scintillator (not shown) for converting radiation into light in a position covering the pixel array 102.

The conversion element 104 includes a first electrode 106 and second electrode 107. The first electrode 106 of the conversion element 104 is connected to the first main electrode of the TFT 105 formed in the same pixel. The second electrode 107 of the conversion element 104 is connected to a power supply circuit 110 via a bias line 111 running in the column direction. The second main electrode of the TFT 105 is connected to a read circuit 120 via a signal line 121 running in the column direction. The control electrode of the TFT 105 is connected to a driving circuit 130 via a driving line 131 running in the row direction.

The read circuit 120 can include, for each signal line 121, an integrating amplifier 122 for integrating and amplifying an electrical signal from the signal line 121, and a sample-and-hold circuit 123 for sampling and holding the electrical signal amplified by the integrating amplifier 122. The read circuit 120 can further include a multiplexer 124 for converting electrical signals output in parallel from a plurality of sample-and-hold circuits 123 into a serial electrical signal, and an A/D converter 125 for converting the output electrical signal from the multiplexer 124 into digital data. The power supply circuit 110 supplies a reference potential Vref to the non-inverting input terminal of the integrating amplifier 122. The power supply circuit 110 further supplies a bias potential Vs to the second electrode 107 of the conversion element 104 via the bias line 111.

Next, an outline of the operation of the detection apparatus 100 will be explained. The power supply circuit 110 applies the reference potential Vref to the first electrode 106 of the conversion element 104 via the TFT 105, and also applies, to the second electrode 107 of the conversion element 104, the bias potential Vs necessary to separate electron-hole pairs generated by radiation or visible light. In this state, radiation transmitted through an object and having entered the conversion element 104 or visible light corresponding to the radiation is converted into electric charge and stored in the conversion element 104. When the TFT 105 is turned on by a driving pulse applied from the driving circuit 130 to the driving line 131, an electrical signal corresponding to the electric charge stored in the conversion element 104 is output to the signal line 121, and read out outside as digital data by the read circuit 120.

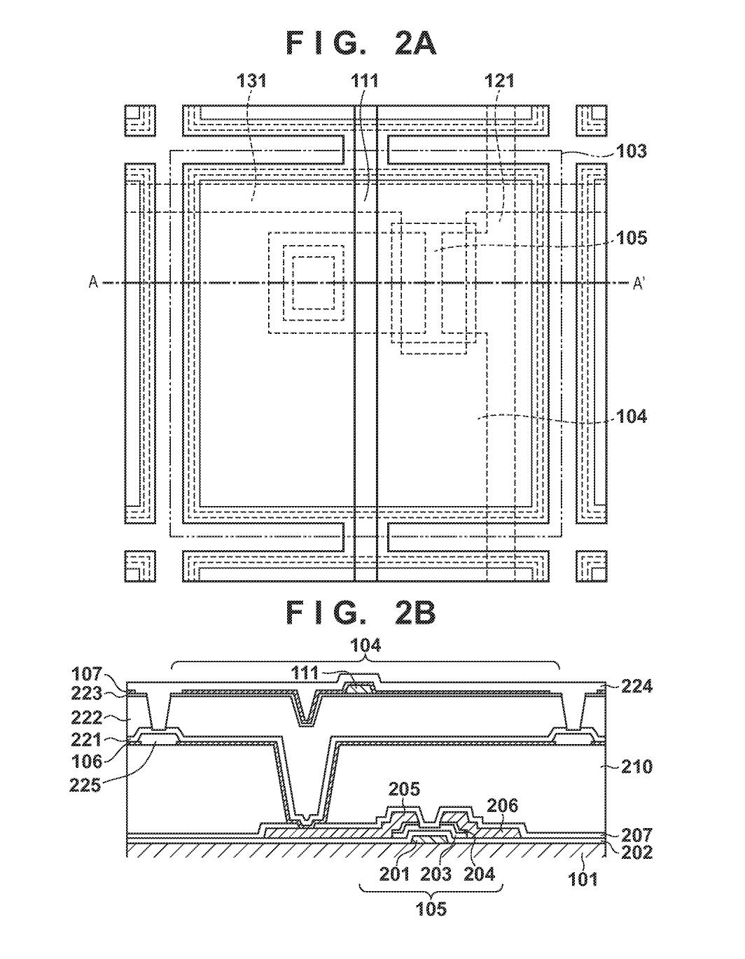

A structure example of the pixel 103 according to the first embodiment of the above-described detection apparatus 100 will be explained with reference to FIGS. 2A and 2B. The arrangement of the detection apparatus 100 except for the pixel 103 can be any arrangement, and an existing arrangement can be used, so an explanation thereof will be omitted. FIG. 2A is a plan view specifically showing one pixel 103 and its periphery, and FIG. 2B is a sectional view taken along a line A-A′ in FIG. 2A. FIG. 2A omits some elements in order to make the drawing easy to see.

As described above, the pixel 103 can include the conversion element 104 and TFT 105. The TFT 105 is formed on the insulating substrate 101 such as a glass substrate, and the conversion element 104 is formed above the TFT 105. An interlayer insulation layer 210 is formed between the TFT 105 and conversion element 104, thereby insulating the TFT 105 and conversion element 104 from each other.

On the substrate 101, the TFT 105 includes a control electrode 201, an insulation layer 202, a semiconductor layer 203, an impurity semiconductor layer 204 having an impurity concentration higher than that of the semiconductor layer 203, a first main electrode 205, and a second main electrode 206, in this order from the surface of the substrate 101. Partial regions of the impurity semiconductor layer 204 are in contact with the first main electrode 205 and second main electrode 206, and a region between those regions of the semiconductor layer 203, which are in contact with the above-mentioned partial regions, is the channel region of the TFT 105. The control electrode 201 of the TFT 105 is electrically connected to the driving line 131. The first main electrode 205 of the TFT 105 is electrically connected to the first electrode 106 of the conversion element 104. The second main electrode 206 of the TFT 105 is electrically connected to the signal line 121. In this embodiment, the first main electrode 205 and second main electrode 206 of the TFT 105 and the signal line 121 are integrally formed by the same conductive pattern, and the second main electrode 206 forms a part of the signal line 121. A protective layer 207 is formed to cover the TFT 105, driving line 131, and signal line 121. In this embodiment, an inverted stagger type TFT having the semiconductor layer 203 containing amorphous silicon as a main material and the impurity semiconductor layer 204 is used as a switching element. However, the switching element may also have another arrangement. For example, it is also possible to use, for example, a stagger type TFT containing polysilicon as a main material, an organic TFT, or an oxide TFT, as the switching element.

The interlayer insulation layer 210 is formed between the substrate 101 and the first electrode 106 of the conversion element 104 so as to cover the TFT 105 of each pixel. The first electrode 106 of the conversion element 104 and the first main electrode 205 of the TFT 105 are connected in a contact hole provided in the interlayer insulation layer 210.

On the interlayer insulation layer 210, the conversion element 104 includes the first electrode 106, an inorganic insulation layer 221, a semiconductor layer 222, an impurity semiconductor layer 223, and the second electrode 107, in this order from the surface of the interlayer insulation layer 210. The second electrode 107 of the conversion element 104 is electrically connected to the bias line 111. The conversion element 104 is covered with a passivation layer 224. In the first embodiment, a MIS photoelectric conversion element including the semiconductor layer 222 containing amorphous silicon as a main material and the impurity semiconductor layer 223 is used as the conversion element 104. However, the conversion element 104 may also have another arrangement. For example, as the conversion element 104, it is also possible to use a conversion element that includes the semiconductor layer 222 containing amorphous selenium as a main material and the impurity semiconductor layer 223 and directly converts radiation into electric charge. The first electrode 106 and second electrode 107 are divided for individual pixels 103, and one pixel 103 includes one first electrode 106 and one second electrode 107. Therefore, both the first electrode 106 and second pixel 107 can be called a pixel electrode. The first electrode 106 can also be called a lower pixel electrode (lower electrode), and the second electrode 107 can also be called an upper pixel electrode (upper electrode). The semiconductor layer 222 and impurity semiconductor layer 223 are also divided for individual pixels 103, and one pixel 103 includes one semiconductor layer 222 and one impurity semiconductor layer 223. The inorganic insulation layer 221 can be formed in common to the plurality of pixels 103.

The interlayer insulation layer 210 may also be an organic insulation layer formed by an organic material having a low dielectric constant and capable of forming a thick film or flat film. This makes it possible to reduce a capacitance generated between the conversion element 104 and TFT 105. It is also possible, by planarizing the upper surface of the interlayer insulation layer 210, to eliminate steps of the TFT 105, driving line 131, and signal line 121, and stably form the conversion element 104 on the interlayer insulation layer 210.

The following relationship holds between an output Qout from the conversion element 104 and a charge amount Qin generated in the semiconductor layer 222 by incident light or radiation:

Qout=G×Qin

where G is the internal gain and represented by:

G=(Ci)/(Ci+Cs)

where Ci is the capacitance value of the inorganic insulation layer 221, and Cs is the capacitance value of the semiconductor layer 222. Accordingly, the value of the output Qout increases as the capacitance value of the inorganic insulation layer 221 increases, so the sensitivity of the conversion element 104 can be increased by decreasing the film thickness of the inorganic insulation layer 221.

The following problem arises when the inorganic insulation layer 221 is thinned. A portion of the inorganic insulation layer 221, which covers the gap between the first electrodes 106 functions as an underlayer during dry etching for dividing the semiconductor layer 222. If this dry etching removes not only the semiconductor layer 222 but also the inorganic insulation layer 221 below the semiconductor layer 222, the interlayer insulation layer 210 made of an organic material is exposed to dry etching, and this may cause contamination by the organic material. As an example, a case in which the inorganic insulation layer 221 is a silicon nitride film and the semiconductor layer 222 is an amorphous silicon film will be examined. As an etching gas for a silicon-based material, a fluorine-based gas such as CF₄ or SF₆ or a chlorine-based gas is generally used. Since the etching selectivity between silicon nitride and amorphous silicon is not infinite in these etching gases, it is difficult to selectively etch only an amorphous silicon film. In addition, an etching rate variation exists in a plane due to a loading effect or the like. Therefore, overetching must be performed to completely remove amorphous silicon from a portion where the etching rate is low. This overetching may completely remove a thinned silicon nitride film from a portion where the etching rate is high. This may cause contamination by the organic material described above.

Accordingly, the detection apparatus 100 according to the first embodiment includes not only the inorganic insulation layer 221 but also an inorganic material portion 225 on the interlayer insulation layer 210 in the position of the gap between the first electrodes 106. Since a stacked structure of the inorganic material portion 225 and inorganic insulation layer 221 functions as an etching stopper, contamination by the organic material as described above can be prevented even when the inorganic insulation layer 221 is thin. It is also possible to reduce the possibility of peel-off of the inorganic material portion 225 from the interlayer insulation layer 210 because the inorganic material portion 225 having a sufficient thickness can remain after etching.

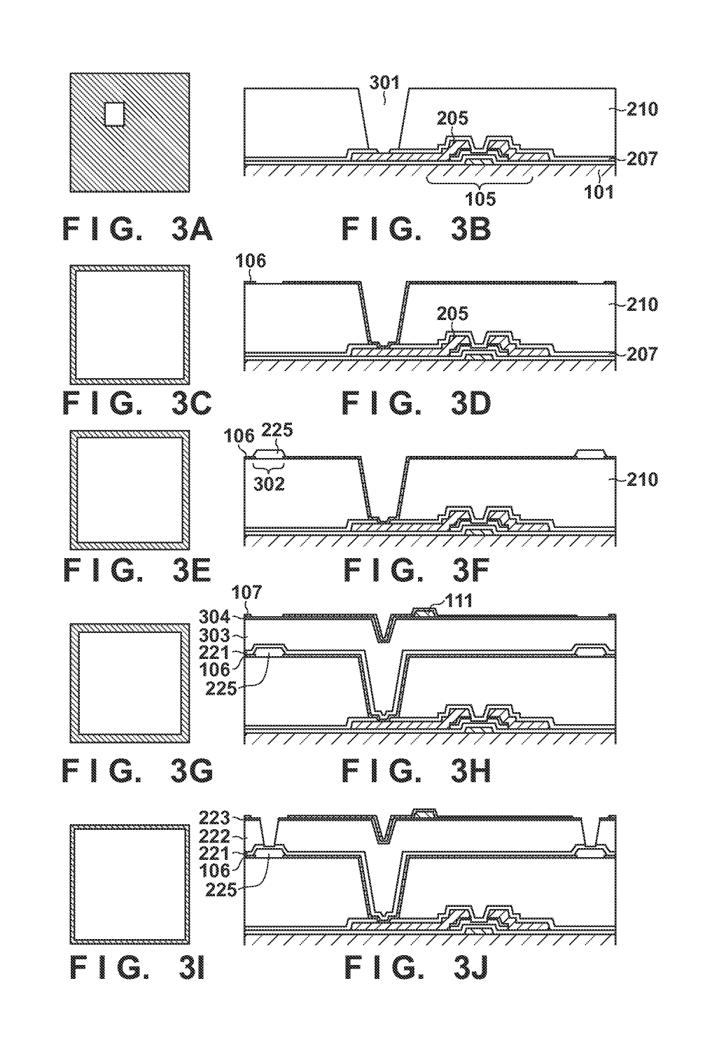

Next, an example of a method of manufacturing the detection apparatus 100 having the structure of the pixel 103 explained with reference to FIGS. 2A and 2B will be explained with reference to FIGS. 3A to 3J. In FIGS. 3A to 3J, a method for forming the interlayer insulation layer 210 and conversion element 104 will be explained in detail. The TFT 105 and other constituent elements of the detection apparatus 100 can be formed by existing methods, so an explanation thereof will be omitted. FIGS. 3B, 3D, 3F, 3H, and 3J correspond to the sectional view of FIG. 2B, and show sectional views in individual steps. Similar to FIG. 2B, these drawings specifically show one pixel 103 and its periphery. Each of FIGS. 3A, 3C, 3E, 3G, and 3I is a schematic plan view of a one-pixel mask pattern of a photomask used in a corresponding step. A hatched portion in each drawing indicates a light-shielding portion. In an actual mask, the one-pixel mask patterns are arranged in the form of an array.

First, in a step shown in FIG. 3B, a substrate 101 including a TFT 105 and a protective layer 207 covering the TFT 105 is prepared. A contact hole for exposing a part of a first main electrode 205 is formed in the protective layer 207. An organic insulation film made of an acrylic resin as a photosensitive organic material is deposited on the substrate 101 so as to cover the TFT 105 and protective layer 207 by using a coating apparatus such as a spinner. A polyimide resin or the like may also be used as the photosensitive organic material. Then, exposure is performed by using a mask shown in FIG. 3A, and development is performed after that, thereby forming a contact hole 301 in the organic insulation film. Thus, an interlayer insulation layer 210 is formed. The contact hole 301 in the interlayer insulation layer 210 exposes the contact hole in the protective layer 207. That is, a portion of the first main electrode 205 is exposed from the contact hole 301 in the interlayer insulation layer 210.

Then, in a step shown in FIG. 3D, an amorphous oxide film made of ITO is deposited by sputtering so as to cover the interlayer insulation layer 210. This oxide film is transparent and conductive. Subsequently, this oxide film is divided for individual pixels by wet etching using a mask shown in FIG. 3C. A plurality of first electrodes 106 are formed by polycrystallizing the divided oxide films by annealing. Although ITO is used as the material of the oxide film in the above-described example, it is also possible to use materials such as ZnO, SnO₂, ATO, AZO, CdIn₂O₄, MgIn₂O₄, ZnGa₂O₄, and InGaZnO₄. As the material of the oxide film, a material that can take an amorphous state such as a Cu-containing delafossite type material, for example, CuAlO₂ may also be used.

Subsequently, in a step shown in FIG. 3F, an inorganic insulation film made of an inorganic material such as a silicon nitride film or silicon oxide is deposited by plasma CVD so as to cover the interlayer insulation layer 210 and first electrode 106. Then, the inorganic insulation film is etched by using a mask shown in FIG. 3E, thereby forming an inorganic material portion 225 in a position covering the gap between the first electrodes 106. More specifically, the inorganic insulation film on a portion except for the edges of the first electrode 106 is removed by etching. Consequently, the inorganic material portion 225 is so formed as to cover a portion 302 of the interlayer insulation layer 210, which is not covered with the plurality of first electrodes 106, and the edges of the first electrode 106.

In a step shown in FIG. 3H, an insulation film made of an inorganic material such as a silicon nitride film or silicon oxide is deposited by plasma CVD so as to cover the inorganic material portion 225 and first electrode 106. This insulation film functions as an inorganic insulation layer 221. After that, a semiconductor film 303 made of an amorphous silicon film and an impurity semiconductor film 304 made of an amorphous silicon film in which a pentavalent element such as phosphorus is mixed as an impurity are deposited in this order by plasma CVD. Then, a conductive film made of Al or the like is deposited by sputtering so as to cover the impurity semiconductor film 304. A bias line 111 is formed by wet-etching this conductive film. Subsequently, an oxide film is deposited by sputtering so as to cover the impurity semiconductor film 304 and bias line 111. This oxide film is transparent and conductive. Then, this oxide film is divided for individual pixels by wet etching using a mask shown in FIG. 3G. The divided oxide films function as a plurality of second electrodes 107. The material of the second electrode 107 can be selected from the same materials as those of the first electrode 106. When the conversion element 104 is an element that directly converts radiation into electric charge, the second electrode 107 need not be transparent, and it is also possible to use a conductive film that readily transmits radiation, for example, Al.

Then, in a step shown in FIG. 3J, the impurity semiconductor film 304 and semiconductor film 303 are divided for individual pixels by dry etching using a mask shown in FIG. 3I. The divided impurity semiconductor films 304 form impurity semiconductor layers 223, and the divided semiconductor films 303 form semiconductor layers 222. In this dry etching, the inorganic material portion 225 on the portion 302 of the interlayer insulation layer 210 functions as an etching stopper. Even when the inorganic insulation layer 221 is completely removed by dry etching, therefore, the interlayer insulation layer 210 below the inorganic material portion 225 is not exposed to dry etching, so contamination by the organic material can be prevented. It is also possible to suppress film peeling of the inorganic material portion 225 caused by the shrinkage of the interlayer insulation layer 210 by forming the inorganic material portion 225 such that the inorganic material portion 225 having a sufficient thickness remains after etching. Finally, the arrangement shown in FIG. 2B is obtained by forming a passivation layer 224 so as to cover the conversion element 104.

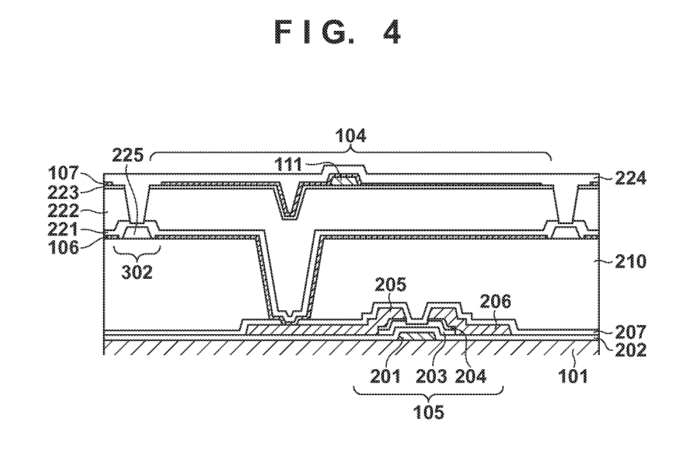

The first modification of the detection apparatus 100 according to the first embodiment will be explained with reference to FIG. 4. FIG. 4 is a sectional view specifically showing one pixel 103 and its periphery, and corresponds to FIG. 2B. The difference of the first modification from the first embodiment is the shape of the inorganic material portion 225. In the first embodiment, the inorganic material portion 225 covers the edges of the first electrode 106. In the first modification, the inorganic material portion 225 is not in contact with the first electrode 106, and covers only a part of the portion 302 of the interlayer insulation layer 210. Since the inorganic material portion 225 functions as an etching stopper in the first modification as well, contamination by the organic material can be prevented. It is also possible to suppress film peeling of the inorganic material portion 225 caused by the shrinkage of the interlayer insulation layer 210. In the first modification, the inorganic material portion 225 is not in contact with the first electrode 106, so the inorganic material portion 225 can be formed by an inorganic insulator such as silicon nitride, and can also be formed by an inorganic conductor such as a metal containing Al or the like. The detection apparatus 100 according to the first modification can be manufactured in the same manner as that for the detection apparatus 100 according to the first embodiment by changing the shape of the mask shown in FIG. 3E.

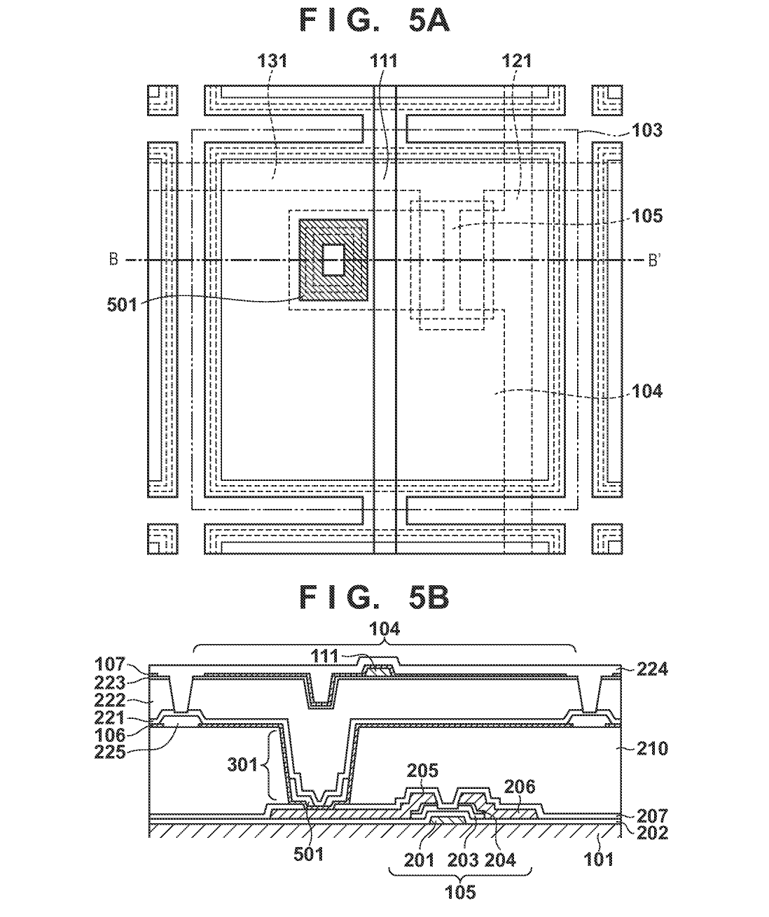

The second modification of the detection apparatus 100 according to the first embodiment will be explained with reference to FIGS. 5A and 5B. FIG. 5A is a plan view specifically showing one pixel 103 and its periphery, and FIG. 5B is a sectional view taken along a line B-B′ in FIG. 5A. FIG. 5A omits some elements in order to make the drawing easy to see.

The second modification differs from the first embodiment in that an inorganic material portion 501 is further included. The inorganic material portion 501 is formed in a position covering the step portions of the first electrode 106, in the contact hole 301 formed in the interlayer insulation layer 210.

The first electrode 106 functions as an underlayer during etching for forming the inorganic material portion 225 explained with reference to FIG. 2F in the first embodiment. The etching rate of a layer to be etched generally changes in accordance with the crystallinity or film thickness. For example, a step is formed in a portion of the first electrode 106, which covers the edges of the protective layer 207, or in a portion of the first electrode 106, which covers the boundary between the interlayer insulation layer 210 and protective film 137. Since the crystallinity weakens in this step portion, the etching rate increases. Consequently, etching sometimes pierces the first electrode 106 and etches the first main electrode 205 and protective layer 207. In the second modification, this step portion can be prevented from being etched by protecting it by the inorganic material portion 501. In the example shown in FIG. 5B, the inorganic material portion 501 covers only the step portions of the first electrode 106. However, the inorganic material portion 501 may also cover the first electrode 106 in the whole contact hole 301.

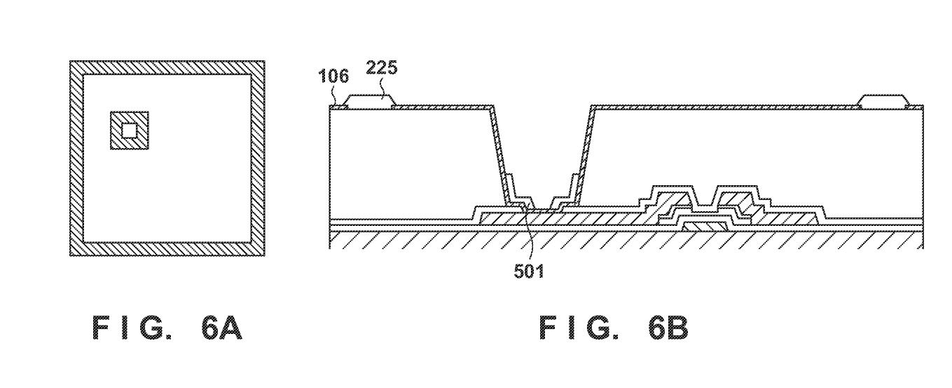

An example of a method of manufacturing the detection apparatus 100 having the structure of the pixel 103 explained with reference to FIGS. 5A and 5B will be explained below with reference to FIGS. 6A and 6B. This method is the same as that of the first embodiment until the step shown in FIG. 3D, so a repetitive explanation will be omitted. Then, in a step shown in FIG. 6B, an inorganic insulation film made of an inorganic material such as a silicon nitride film or silicon oxide is deposited by plasma CVD so as to cover an interlayer insulation layer 210 and first electrode 106. Subsequently, the inorganic insulation film is etched by using a mask shown in FIG. 6A, thereby forming inorganic material portions 225 and 501. Steps after that are the same as those from the step shown in FIG. 3H, so a repetitive explanation will be omitted.

The detection apparatus 100 according to the second modification can also have the same effect as that of the first embodiment. In addition, the first and second modifications can be combined. In this case, the inorganic material portion 501 may also be formed by an inorganic film of an inorganic conductor.

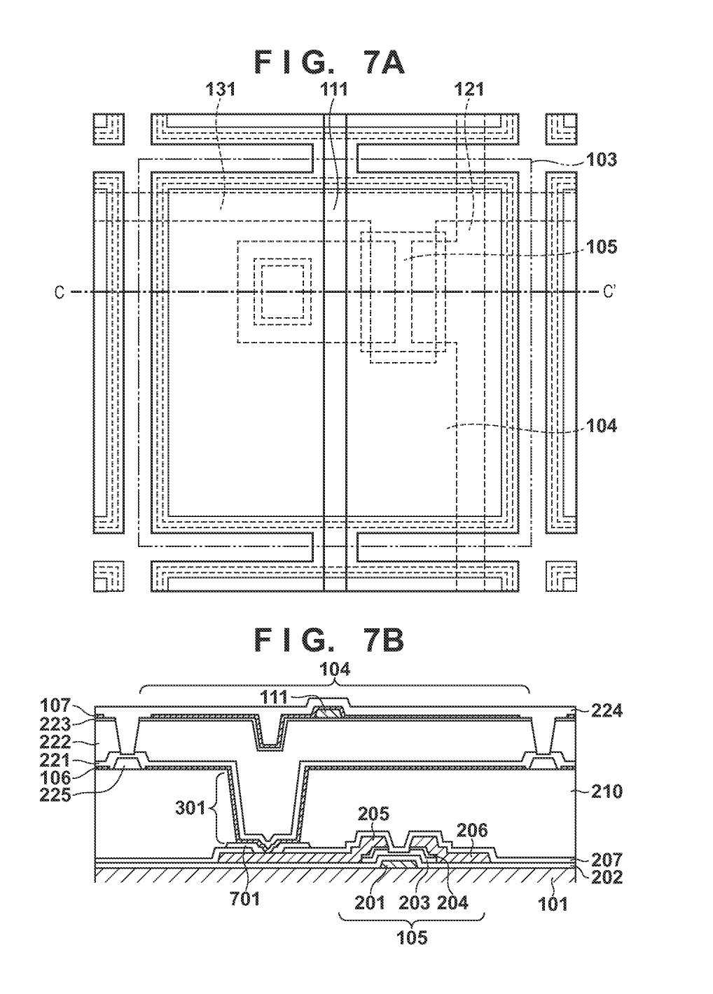

The third modification of the detection apparatus 100 according to the first embodiment will be explained with reference to FIGS. 7A and 7B. FIG. 7A is a plan view specifically showing one pixel 103 and its periphery, and FIG. 7B is a sectional view taken along a line C-C′ in FIG. 7A. FIG. 7A omits some elements in order to make the drawing easy to see.

The third modification differs from the first embodiment in that an inorganic material portion 701 is further included. The inorganic material portion 701 is formed below the steps of the first electrode 106 in the contact hole 301 formed in the interlayer insulation layer 210. More specifically, the inorganic material portion 701 is formed between the first electrode 106 and first main electrode 205, and between the first electrode 106 and protective layer 207. In the third modification, it is possible to prevent the first main electrode 205 and protective layer 207 from being etched because the inorganic material portion 701 functions as an etching stopper.

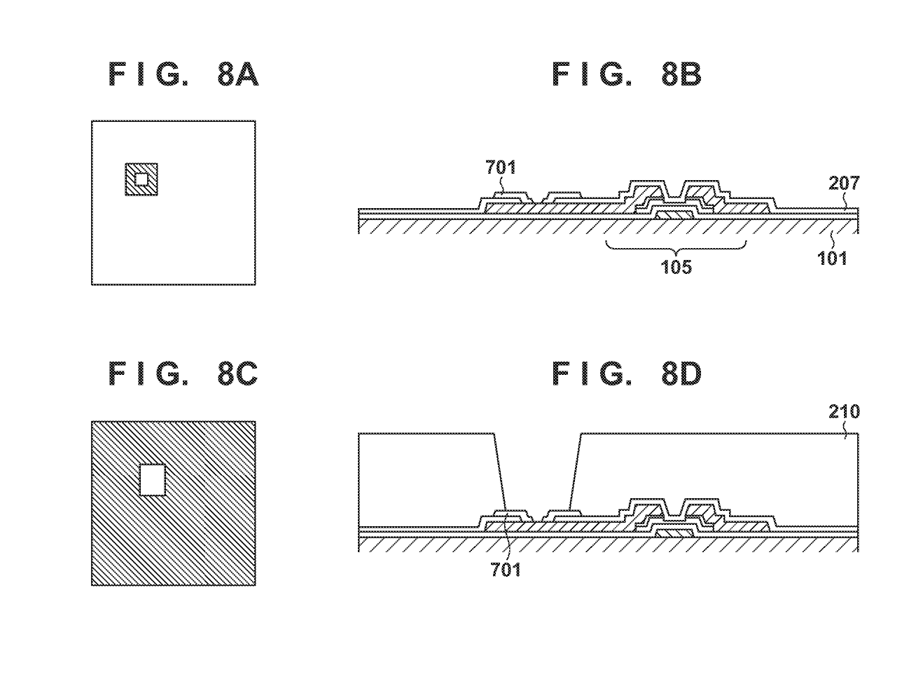

An example of a method of manufacturing the detection apparatus 100 having the structure of the pixel 103 explained with reference to FIGS. 7A and 7B will be explained below with reference to FIGS. 8A to 8D. In a step shown in FIG. 8B, a substrate 101 including a TFT 105 and a protective layer 207 covering the TFT 105 is prepared in the same manner as in the first embodiment. Then, an inorganic insulation film made of an inorganic material such as a silicon nitride film is deposited by plasma CVD so as to cover the TFT 105 and protective layer 207. Subsequently, an inorganic material portion 701 is formed by etching this inorganic insulation film by using a mask shown in FIG. 8A. The inorganic material portion 701 may also be formed by an organic conductor such as Al.

Then, in a step shown in FIG. 8D, an interlayer insulation layer 210 is formed by using a mask shown in FIG. 8C in the same manner as in FIG. 3B. Steps after that are the same as those from the step shown in FIG. 3D, so a repetitive explanation will be omitted.

The detection apparatus 100 according to the third modification can also have the same effect as that of the first embodiment. It is also possible to combine the first and third modifications, or the second and third modifications. Furthermore, all of the first to third modifications can be combined at the same time. These modifications and their combinations can also be applied to arbitrary embodiments below.

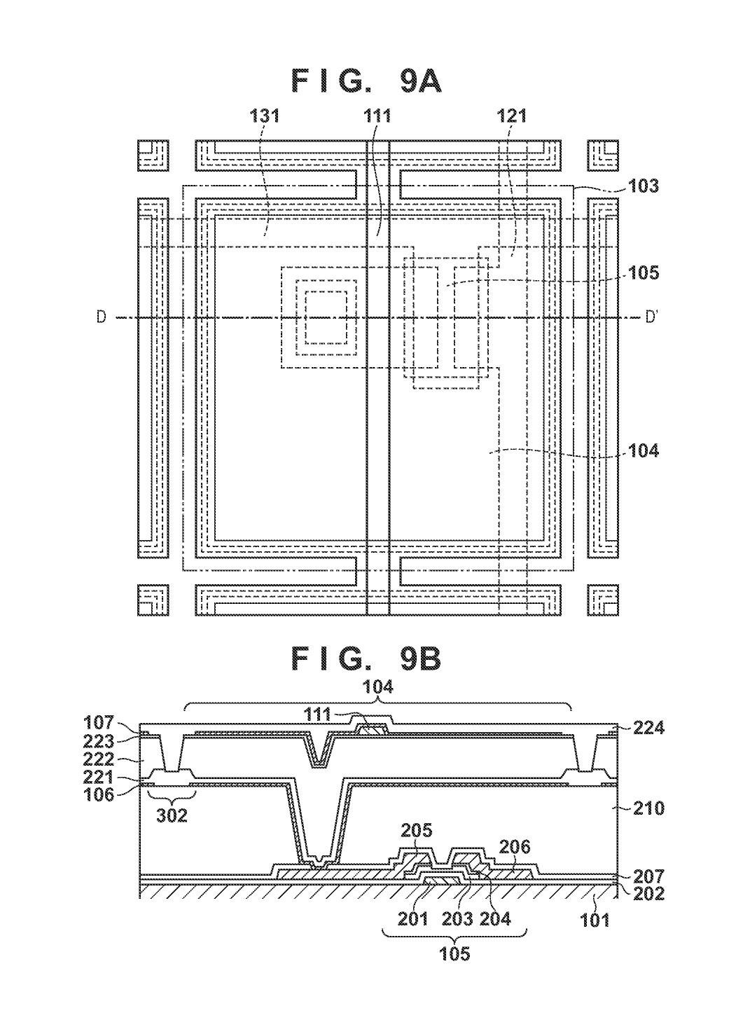

A structure example of a pixel 103 according to the second embodiment of the above-described detection apparatus 100 will be explained with reference to FIGS. 9A and 9B. The arrangement of the detection apparatus 100 except for the pixel 103 can be any arrangement, and an existing arrangement can be used, so an explanation thereof will be omitted. FIG. 9A is a plan view specifically showing one pixel 103 and its periphery, and FIG. 9B is a sectional view taken along a line D-D′ in FIG. 9A. FIG. 9A omits some elements in order to make the drawing easy to see.

The second embodiment differs from the first embodiment in that no inorganic material portion 225 is formed. In addition, the shape of an inorganic insulation layer 221 is another difference between these embodiments. The inorganic insulation layer 221 of the second embodiment has a portion having the largest height from a substrate 101, on a portion 302 of an interlayer insulation layer 210. This thickness achieves the same effect as that of the first embodiment.

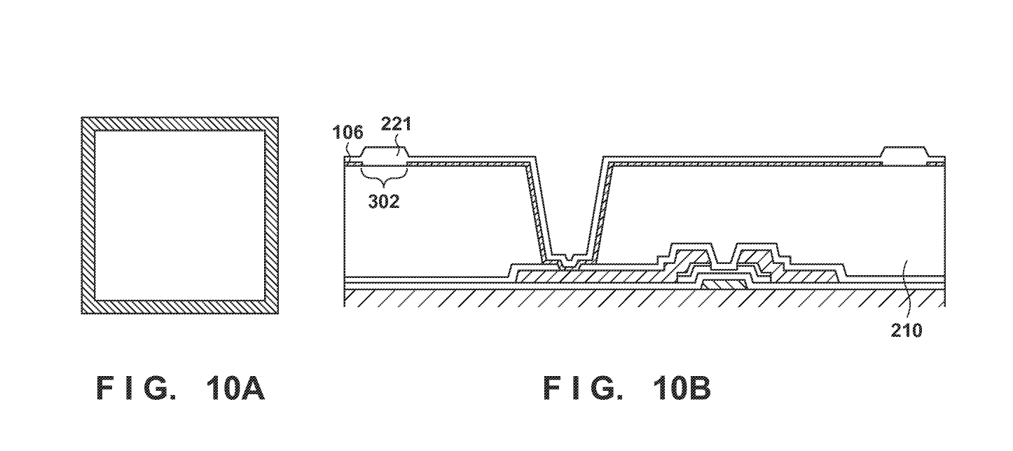

An example of a method of manufacturing the detection apparatus 100 having the structure of the pixel 103 explained with reference to FIGS. 9A and 9B will be explained below with reference to FIGS. 10A and 10B. Since the method is the same as that of the first embodiment until the step shown FIG. 3D, a repetitive explanation will be omitted. Then, in a step shown in FIG. 10B, an inorganic insulation film made of an inorganic material such as a silicon nitride film or silicon oxide is deposited by plasma CVD so as to cover an interlayer insulation layer 210 and first electrode 106. After that, the insulation film on the first electrode 106 is etched by using a mask shown in FIG. 10A until a desired thickness is obtained, thereby forming an inorganic insulation layer 221. Since this mask covers the insulation film on a portion 302 of the interlayer insulation layer 210, a portion on the portion 302 of the interlayer insulation layer 210 is not etched. Therefore, the thickness of that portion of the inorganic insulation layer 221, which exists on the portion 302 of the interlayer insulation layer 210, can be made larger than that of the portion existing on the first electrode 106. Steps after that are the same as those from the step shown in FIG. 3H, so a repetitive explanation will be omitted.

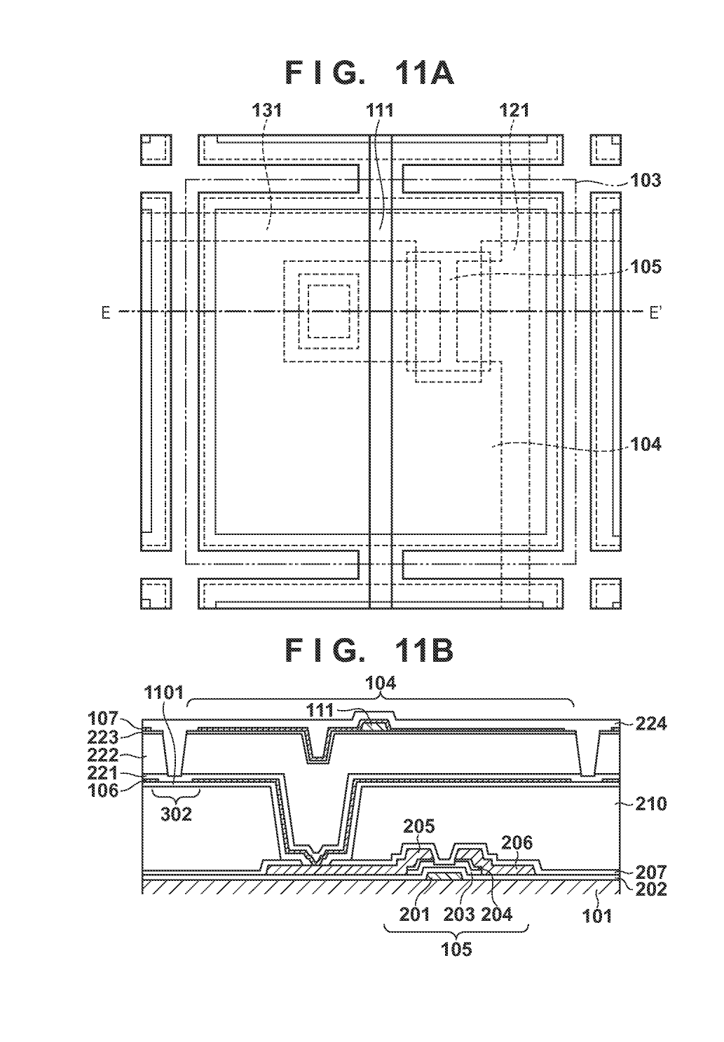

A structure example of a pixel 103 according to the third embodiment of the above-described detection apparatus 100 will be explained with reference to FIGS. 11A and 11B. The arrangement of the detection apparatus 100 except for a pixel 103 can be any arrangement, and an existing arrangement can be used, so an explanation thereof will be omitted. FIG. 11A is a plan view specifically showing one pixel 103 and its periphery, and FIG. 11B is a sectional view taken along a line E-E′ in FIG. 11A. FIG. 11A omits some elements in order to make the drawing easy to see.

The third embodiment differs from the first embodiment in that no inorganic material portion 225 is formed and an insulation layer 1101 is formed. In the third embodiment, the total of the thickness of an inorganic insulation layer 221 on a portion 302 of an interlayer insulation layer 210 and the thickness of the insulation layer 1101 is larger than the thickness of the inorganic insulating layer 221 on a first electrode 106. The same effect as that of the first embodiment is obtained because a stacked structure of the inorganic insulation layer 221 and insulation layer 1101 functions as an etching stopper.

In the pixel 103, the insulation layer 1101 is formed below the first electrode 106 on the entire surface except for a contact hole to a first main electrode 205. Therefore, the first electrode 106 may also be formed by a metal material instead of an oxide film, in order to improve adhesion between the insulation layer 1101 and first electrode 106.

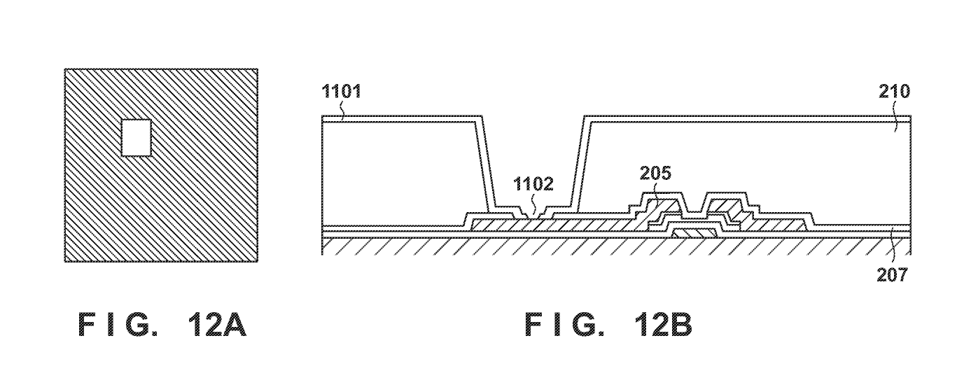

An example of a method of manufacturing the detection apparatus 100 having the structure of the pixel 103 explained with reference to FIGS. 11A and 11B will be explained below with reference to FIGS. 12A and 12B. Since the method is the same as that of the first embodiment until the step shown FIG. 3B, a repetitive explanation will be omitted. Then, in a step shown in FIG. 12B, an insulation film made of an inorganic material such as a silicon nitride film or silicon oxide is deposited by plasma CVD so as to cover an interlayer insulation layer 210. After that, the insulation film is etched by using a mask shown in FIG. 12A, thereby forming a contact hole 1102 that exposes a portion of a first main electrode 205. Thus, an insulation layer 1101 is formed. Steps after that are the same as those from the step shown in FIG. 3D, so a repetitive explanation will be omitted.

In any of the above-described first to third embodiments, the thickness of an inorganic portion functioning as an etching stopper can be increased even when the inorganic insulation layer 221 is thinned. Practical examples of the thickness of the etching stopper before the semiconductor film 303 is etched will be examined below.

Assume that the material of the semiconductor film 303 is amorphous silicon, the material of the etching stopper is silicon nitride, and the main component of an etching gas for etching the semiconductor film 303 is a fluorine-based gas. The etching selectivity between amorphous silicon and silicon nitride with respect to the fluorine-based gas is about 1:1. When an etching rate variation in a plane caused by the loading effect or the like is ±10%, therefore, overetching of at least 10% is necessary to completely remove amorphous silicon from a portion where the etching rate is low. When overetching of 20% is performed in order to secure a process margin, this overetching results in, according to calculations, overetching of 30% in a portion where the etching rate is high. As a consequence, when the thickness of the semiconductor film 303 is 1,000 nm, the etching stopper is overetched by about 300 nm in a portion where the etching rate is high. If the thickness of the etching stopper after etching is 50 nm or less, film peeling of the etching stopper may occur in a later heating step. In the above-described example, therefore, an etching stopper need only be formed such that the thickness of the etching stopper before etching is 350 nm or more.

When the main component of the etching gas for etching the semiconductor film 303 is a chlorine-based gas, the selectivity between amorphous silicon and silicon nitride is about 4:1. In accordance with the same calculations as in the above-described example, therefore, an etching stopper need only be formed such that the thickness of the etching stopper before etching is 125 nm or more.

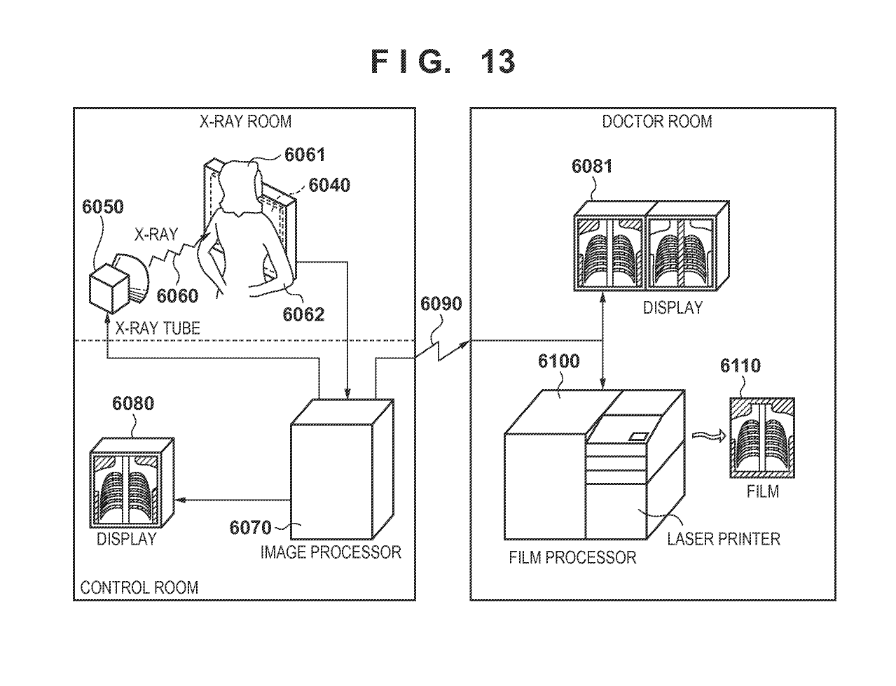

FIG. 13 is a view showing an application example of the radiation detection apparatus according to the present invention to a radiation diagnostic system (radiation detection system). X-rays 6060 generated as radiation by an X-ray tube 6050 (radiation source) are transmitted through a chest region 6062 of an object or patient 6061 and enter a detection apparatus 6040 in which a scintillator is arranged in an upper portion. The detection apparatus 6040 can be a detection apparatus according to any of the above-described embodiments. A detection conversion apparatus in which a scintillator is arranged in an upper portion forms a radiation detection apparatus. The incident X-rays include information about the inside of the body of the patient 6061. The scintillator emits light as X-rays enter, and electrical information is obtained by photoelectric conversion. This information is converted into a digital signal. An image processor 6070 as a signal processing unit performs image processing on the signal. The processed signal can be observed on a display 6080 as a display unit in a control room. The radiation detection system includes at least a detection apparatus, and a signal processing unit for processing a signal from the detection apparatus.

In addition, it is possible to transfer this information to a remote place by a transmission processing unit such as a telephone line 6090. The transferred information can be displayed on a display 6081 as a display unit in another place, for example, a doctor room. Furthermore, it is possible to store this information in a recording unit such as an optical disk. In this manner, another doctor in a remote place can diagnose the object. A film processor 6100 serving as a recording unit can record the information on a film 6110 as a recording medium.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-118302, filed Jun. 4, 2013, which is hereby incorporated by reference herein in its entirety.

What is claimed is:

1. A method of manufacturing a detection apparatus including a plurality of pixels, comprising:
forming an organic insulation layer above a substrate above which a switching element is formed;
forming a plurality of pixel electrodes divided for individual pixels above the organic insulation layer;
forming an inorganic material portion above a portion of the organic insulation layer, which is uncovered with the plurality of pixel electrodes;
forming an inorganic insulation film covering the plurality of pixel electrodes and the inorganic material portion;
forming a semiconductor film covering the inorganic insulation film; and
dividing the semiconductor film for individual pixels by etching using a stacked structure of the inorganic material portion and the inorganic insulation film as an etching stopper.

2. The method according to claim 1, wherein the forming the inorganic material portion comprises:
covering the uncovered portion of the organic insulation layer and the plurality of pixel electrodes with an inorganic film; and
removing a portion of the inorganic film, which covers at least a part of the plurality of pixel electrodes, by etching.

3. The method according to claim 1, wherein the inorganic material portion covers the uncovered portion of the organic insulation layer and edges of the plurality of pixel electrodes.

4. The method according to claim 1, wherein the inorganic material portion covers a part of the uncovered portion of the organic insulation layer, and is not in contact with the plurality of pixel electrodes.

5. The method according to claim 1, wherein the inorganic material portion is formed by an inorganic insulator.

6. The method according to claim 1, wherein the inorganic material portion is formed by an inorganic conductor.

7. A method of manufacturing a detection apparatus including a plurality of pixels, comprising:
forming an organic insulation layer above a substrate above which a switching element is formed;
forming a plurality of pixel electrodes divided for individual pixels above the organic insulation layer;
forming an inorganic insulation film covering the plurality of pixel electrodes and a portion of the organic insulation layer, which is uncovered with the plurality of pixel electrodes;
reducing, by etching, a thickness of a second portion of the inorganic insulation film, which exists above the plurality of pixel electrodes, by using a mask covering a first portion of the inorganic insulation film, which exists above the uncovered portion of the organic insulation layer;
forming a semiconductor film covering the inorganic insulation film; and
dividing the semiconductor film for individual pixels by etching using the first portion of the inorganic insulation film as an etching stopper.

8. A method of manufacturing a detection apparatus including a plurality of pixels, comprising:
forming an organic insulation layer above a substrate above which a switching element is formed;
forming an inorganic insulation layer above the organic insulation layer;
forming a plurality of pixel electrodes divided for individual pixels above the inorganic insulation layer;
forming an inorganic insulation film covering the plurality of pixel electrodes and a portion of the inorganic insulation layer, which is uncovered with the plurality of pixel electrodes;
forming a semiconductor film covering the inorganic insulation film; and
dividing the semiconductor film for individual pixels by etching using a stacked structure of the inorganic insulation layer and the inorganic insulation film as an etching stopper.

9. The method according to claim 8, wherein
the forming the organic insulation layer comprises:
forming an organic insulation film above the substrate above which the switching element is formed; and
forming the organic insulation layer by forming, in the organic insulation film, a contact hole which exposes a portion of an electrode of the switching element, and
the method further comprises forming an inorganic material portion covering a step portion of the pixel electrode in the contact hole.

10. A detection apparatus including a plurality of pixels, comprising:
a switching element formed above a substrate;
an organic insulation layer formed above said switching element;
a plurality of pixel electrodes formed above said organic insulation layer and divided for individual pixels;
an inorganic material portion formed above a portion of said organic insulation layer, which is uncovered with said plurality of pixel electrodes;
an inorganic insulation layer formed above said plurality of pixel electrodes; and
a semiconductor layer formed above said inorganic insulation layer and divided for individual pixels.

11. A detection apparatus including a plurality of pixels, comprising:
a switching element formed above a substrate;
an organic insulation layer formed above said switching element;
a plurality of pixel electrodes formed above said organic insulation layer and divided for individual pixels;
an inorganic insulation layer covering a portion of said organic insulation layer, which is uncovered with said plurality of pixel electrodes, and said plurality of pixel electrodes; and
a semiconductor layer formed above said inorganic insulation layer and divided for individual pixels, and
a portion of said inorganic insulation layer, which has a largest height from said substrate, exists above the uncovered portion of said organic insulation layer.

12. A detection apparatus including a plurality of pixels, comprising:
a switching element formed above a substrate;
an organic insulation layer formed above said switching element;
a first inorganic insulation layer formed above said organic insulation layer and having a contact hole which exposes a portion of an electrode of said switching element;
a plurality of pixel electrodes formed above said first inorganic insulation layer and divided for individual pixels;
a second inorganic insulation layer formed above said plurality of pixel electrodes; and
a semiconductor layer formed above said second inorganic insulation layer and divided for individual pixels.

13. A radiation detection system comprising:
a detection apparatus cited in claim 10; and
a signal processing unit configured to process a signal obtained by said detection apparatus.

14. A radiation detection system comprising:
a detection apparatus cited in claim 11; and
a signal processing unit configured to process a signal obtained by said detection apparatus.

15. A radiation detection system comprising:
a detection apparatus cited in claim 12; and
a signal processing unit configured to process a signal obtained by said detection apparatus.
